(19) United States
(12) Patent Application Publication
(10) Pub. No.: US 2006/0014351 A1
(43) Pub. Date: Jan. 19, 2006

(54) Low leakage MOS transistor

(76) Inventors: Cheng-Yao Lo, Taipei (TW); Hsien-Chin Lin, Kaohsiung (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/891,577

(22) Filed: Jul. 15, 2004

(51) Int. Cl. H01L 21/4763; H01L 21/336; H01L 21/44

(52) U.S. Cl. 438/305; 438/303; 438/592; 438/664

(57) ABSTRACT

A method of forming a low leakage MOS transistor. The transistor includes a gate on a substrate with at least two first spacers adjacent to the gate. A first doped region is formed under each first spacer and a second doped region is formed adjacent to each first doped region, wherein the first doped region and the second doped region are formed in the substrate. A second spacer is formed adjacent to each first spacer. A metal layer is formed on the exposed substrate, the first spacers and the second spacers. The substrate is annealed to form salicide regions on the exposed substrate.

### BACKGROUND OF THE INVENTION

1. Field of the Invention

The present invention relates to a fabrication method and structure for a semiconductor device, and more particularly, to a low leakage MOS transistor using a second spacer.

2. Description of the Related Art

In the field of semiconductor integrated circuits, composite materials comprising silicon and a transition metal such as Ti, Co and the like, called silicides, are used for forming layers having a relatively small resistivity.

In particular, silicides are formed on active areas of MOS transistors for reducing the sheet resistance of source and drain diffusion regions.

A known method for forming a silicide layer on the active areas of MOS transistors comprises forming a gate of the transistor, comprising a gate oxide layer and a polysilicon layer, introducing into the silicon a dopant for formation of the source and drain diffusion regions of the transistors, and then depositing, over the whole surface of the silicon, a transition metal, such as Ti or Co, and performing a thermal process during which the transition metal reacts with the silicon to create the silicide. Since the silicide layer formed on the active area of the MOS transistor is automatically aligned with the gate, the process is referred to as “self-aligned-silicidation”, or simply “salicidation”, and the layer thus obtained is correspondingly referred to as “salicide”.

A drawback of silicides is the consumption of part of the silicon at the interface during the reaction between silicon and the transition metal. As shown in FIG. 1, in an advanced MOS device the lightly doped drain (LDD) 102 junction is very shallow, thus shortening the leakage path from the salicide region 104 to the LDD 104 boundary, and increasing leakage current. One solution is to reduce the silicide 104 thickness. However, thin silicide generates high sheet resistance and diminishes MOS transistor performance.

In general, the gate 112 includes a gate dielectric layer 108 and a spacer 110 adjacent thereto, wherein the spacer includes an oxide layer 114 and a nitride layer 116. The oxide layer 114 of the first spacer 110 is easily etched during subsequent etching or cleaning, whereby the gate dielectric layer 108 is easily damaged through etched oxide layer 114 of the spacer 110, reducing device gate oxide integrity (GOI).

U.S. Pat. No. 6,536,806 discloses a method for fabricating a semiconductor device. In a high speed device structure consisting of a salicide, in order to fabricate a device having at least two gate oxide structures in the identical chip, an LDD region of a core device region is formed, and an ion implant process for forming the LDD region of an input/output device region having a thick gate oxide and a process for forming a source/drain region at the rim of a field oxide of the core device region having a thin gate oxide are performed at the same time, thereby increasing depth of a junction region. Thus, the junction leakage current is decreased in the junction region of the peripheral circuit region, and the process is simplified. As a result, process yield and reliability of the device are improved.

### SUMMARY OF THE INVENTION

An object of the present invention is to provide a fabrication method and a structure for a low leakage MOS transistor with longer junction leakage path to reduce leakage.

Another object of the present invention is to provide a second spacer for protecting an oxide layer of a first spacer in a MOS transistor, thus eliminating oxide layer damage by subsequent cleaning.

To obtain the above objects, the present invention provides a method of forming a low leakage gate. A substrate comprising a gate disposed thereon is provided. The substrate is implanted using a first mask to form a provisional doped region. Next, the substrate is implanted using a second mask to form a second doped region and define a first doped region, wherein the first doped region is a portion of the provisional doped region, comprising a first side adjacent to the gate and a second side. The second doped region is deeper than the first doped region and adjacent to the second side of the first doped region. A salicide region is formed using a third mask, each disposed in the second doped region. The first, second and third masks are of different patterns.

To obtain the above objects, the present invention also provides a low leakage MOS transistor structure. A gate is disposed on a substrate. At least two electrodes are disposed in the substrate and adjacent to the gate, wherein each electrode comprises a first doped region, a second doped region and a salicide region. The first doped region comprises a first side adjacent to the gate and a second side. The second doped region is deeper than the first doped region and adjacent to the second side of the first doped region. The salicide region is disposed in the second doped region and spaced from the second side of the first doped region by a distance defined by a mask.

### BRIEF DESCRIPTION OF THE DRAWINGS

The present invention can be more fully understood by reading the subsequent detailed description in conjunction with the examples and references made to the accompanying drawings, wherein:

FIG. 1 is a cross, section of a conventional MOS transistor;

FIGS. 2A to 2F show a low leakage MOS transistor formed utilizing processing steps that include the method of the present invention.

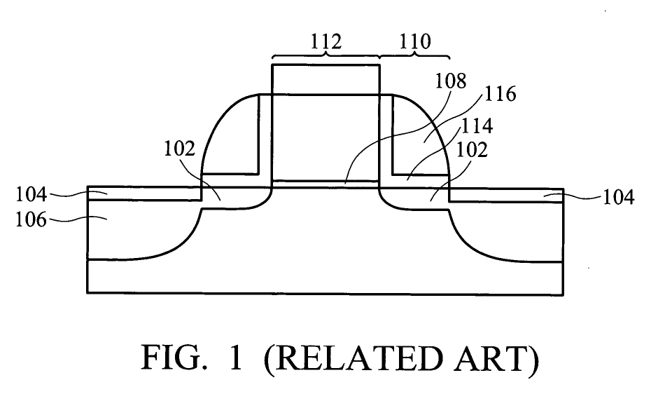

### DETAILED DESCRIPTION OF THE INVENTION

The present invention, which provides a fabricating method and structure of a low leakage MOS transistor, is described in greater detail by referring to the drawings that accompany the present invention. It is noted that in the accompanying drawings, like and/or corresponding elements are referred to by like reference numerals.

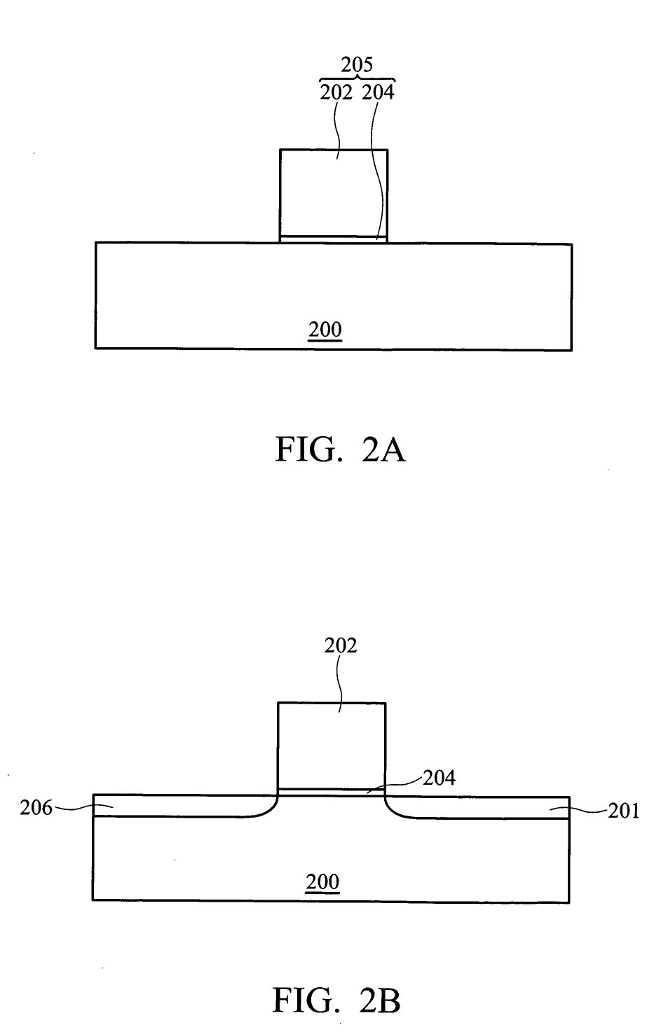

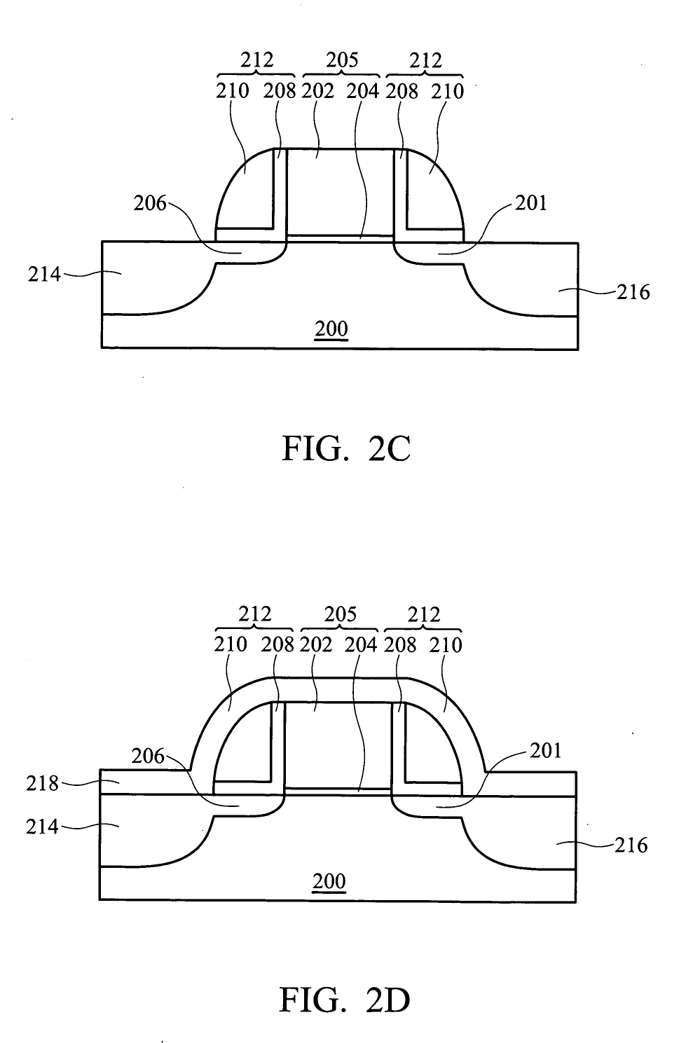

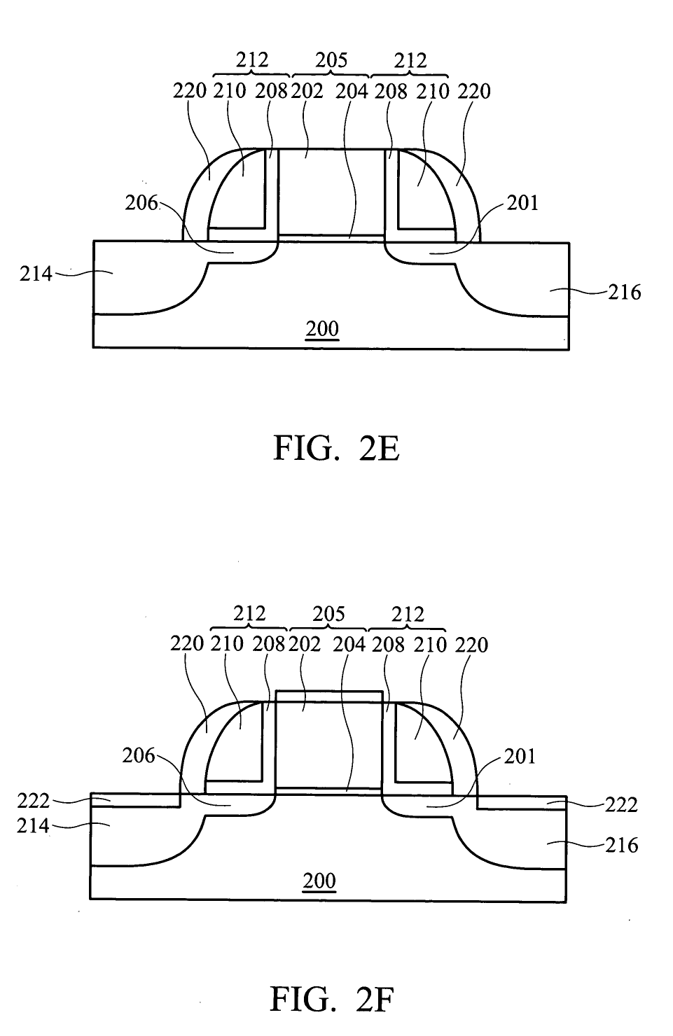

A method of manufacturing a low leakage MOS transistor is described with reference to FIG. 2A to FIG. 2F.

As shown in FIG. 2A, a substrate 200 is provided, and a gate dielectric layer 204 and a gate conductive layer 202 are formed thereon. The substrate 200 can be a semiconductor comprising, for example, a semiconductor material such as Si, Ge, SiGe, GaAs, InAs, InP, Si/Si, Si/SiGe, and silicon-on-insulators. The gate conductive layer 202 can be poly silicon or metal, such as W or Ti, and the gate dielectric layer 204 silicon oxide or any high k dielectric material. The substrate 200 can be n-type or p-type, preferably, p-type. The gate conductive layer 202 and the gate dielectric layer 204 are patterned by photo lithography and etching to form a gate 205. The gate 205 can be a poly gate or a metal gate.

Referring to FIG. 2B, the substrate 200 is ion implanted using the gate 202 as a first mask to form two provisional doped regions 201 in the substrate 200. Preferably, the dopants are As or P, the first regions 206 are n-type, and junction depth is 200 Å˜400 Å.

As shown in FIG. 2C, a first and a second dielectric layer 208 and 210 are formed on the substrate 200. In the preferred embodiment of the present invention, the first dielectric layer 208 is silicon oxide and the second dielectric layer 210 is silicon nitride. The first and second dielectric layers 208 and 210 are preferably formed by chemical vapor deposition, in which the first dielectric layer 208 is deposited using TEOS as a silicon source. The first and second dielectric layer 208 and 210 are then etched to form two first spacers 212 adjacent to the gate 205. Preferably, the etching used is anisotropic. Next, the substrate 200 is implanted with dopants, such as As or P, using the gate 205 and the first spacers 212 as a second mask to form two second doped regions 214 and 216, and two first doped regions 206 are defined. The first doped regions serve as lightly doped drain regions (LDDs). The first and second doped regions serve as source region or a drain region respectively. Preferably, the second doped regions 214 and 216 junction depth is 1000 Å˜2000 Å.

Referring to FIG. 2D, a third dielectric layer 218 is formed on the gate 202, the spacers 212 and the substrate 200. The third dielectric layer 218 can be silicon nitride or silicon oxy-nitride with a thickness of 500 Å˜1200 Å. The third dielectric layer 218 can be formed by any deposition method, for example physical vapor deposition (PVD), low pressure chemical vapor deposition (LPCVD), plasma enhanced chemical vapor deposition (PECVD) or high density plasma enhanced chemical vapor deposition (HDPCVD). In the preferred embodiment of the invention, the third dielectric layer is deposited by LPCVD.

As shown in FIG. 2E, the third dielectric layer is etched anisotropically to form a second spacer 220 adjacent to each first spacer 212. The preferred width of the second spacer 220 is 100 Å˜500 Å. Accordingly, the first dielectric layer 208 adjacent to the substrate 200 is well protected from damage during subsequent etching or cleaning by the second spacer 220. More specifically, the oxide material of the first dielectric layer 208 is protected from etching during HF dipping. Since the first dielectric layer 208 adjacent to the substrate 200 is well protected, infringement of gate dielectric layer 204 through the damaged first dielectric layer 208 is eliminated, resulting in better gate oxide integrity (GOI).

Preferably, process temperature of the above described LPCVD process is below 500° C. to reduce thermal budget, and the process pressure is ranging from 0.1 to 1 Torr.

As shown in FIG. 2F, a metal layer (not shown), such as Ti, Co or Ni, is formed on the gate 202, first and second spacers 212 and 220, and exposed substrate 200. The gate, the first spacer and the second spacer serve as a third mask, such that the metal layer can only contact the exposed portion of the substrate 200. The substrate is annealed such that the metal layer and the exposed substrate 200 interfuse with each other to form two salicide regions 222. The salicide regions 222 can be titanium silicide, cobalt silicide or nickel silicide. Preferably, the annealing temperature is 400˜1000° C. and the salicide region 220 thickness 100 Å˜500 Å. Due to the second spacers 220 on the substrate 200, each salicide region 222 is spaced from the first doped region 206 by the width of the second spacer 220. Consequently, the salicide region 220 is further from the first doped region 206, increasing junction leakage path (from salicide region 222 to first doped region 206 boundary). As salicide thickness is not reduced in the prevent invention, lower junction leakage is provided without diminishing MOS transistor performance. Finally, the non-reactive portion of the metal layer is removed with wet etching.

FIG. 2F is a cross section of a low leakage MOS transistor of the present invention. A gate 202 is disposed on a substrate 200. At least two first spacers 212 are adjacent to the gate 202, wherein each first spacer 212 comprises a first dielectric layer 208 and a second dielectric layer 210. Preferably, the first dielectric layer is silicon oxide and the second dielectric layer silicon nitride.

A first doped region 206 is disposed under each first spacer 212 and in the substrate 200. A second doped region 214 is disposed adjacent to each first doped region 206, wherein the first doped region 206 serves as a LDD and the second doped region 214 as a source or a drain. A second spacer 220 is adjacent to each first spacer 212, wherein the second spacer 220 can be silicon nitride or silicon oxide nitride. A salicide region 222, such as titanium silicide, cobalt silicide or nickel silicide, is disposed in the substrate 200, spaced from the first doped region 206 by the width of the second spacer 220. Sheet resistances of the first doped region, the second doped region and the salicide region are R1, R2 and R3 respectively, wherein R1>R2>R3. Depths of the first doped region, the second doped region and the salicide region are D1, D2 and D3 respectively, wherein D2>D1>D3.

Additionally, due to the longer leakage path provided by the present invention, lower leakage from the source region 214 or the drain region 216 to ground, lower leakage from Bit line to ground, and lower failure rate of GOI break down are achieved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of forming a low leakage MOS transistor, comprising the steps of:
providing a substrate having a gate disposed thereon;
implanting the substrate using the gate as a first mask;
forming at least two first spacers adjacent to the gate;
implanting the substrate using the gate and the first spacers as a second mask;
forming at least two second spacers adjacent to the first spacers; and
forming at least two salicide regions adjacent to the second spacer and in the substrate using the gate, the first spacers and the second spacers as a third mask.

2. The method as claimed in claim 1, wherein the first spacers are stacked films of silicon oxide and silicon nitride.

3. The method as claimed in claim 1, wherein the second spacers are silicon nitride or silicon oxy-nitride.

4. The method as claimed in claim 1, wherein the second spacers have a width of 100 Å˜500 Å.

5. The method as claimed in claim 1, wherein the second spacer is formed by LPCVD or PECVD.

6. A method of forming a low leakage MOS transistor having the steps of:
providing a substrate, comprising a gate disposed thereon;
implanting the substrate using a first mask to form a provisional doped region;
implanting the substrate using a second mask to form a second doped region and define a first doped region, wherein the first doped region is a portion of the provisional dope region, comprising a first side adjacent to the gate and a second side, the second doped region deeper than the first doped region and adjacent to the second side of the first doped region; and
forming a salicide region using a third mask, each salicide region disposed in the second doped region, wherein the first, second and third masks are of different patterns.

7. The method as claimed in claim 6, wherein the first mask is the gate.

8. The method as claimed in claim 6, wherein the second mask comprises the gate and two first spacers adjacent thereto.

9. The method as claimed in claim 8, wherein the third mask comprises the gate, the two first spacers and a second spacer adjacent to each thereof.

10. A structure of a low leakage MOS transistor, comprising:
a substrate;
a gate disposed on the substrate; and
at least two electrodes disposed in the substrate and adjacent to the gate, wherein each electrode comprises a first doped region, a second doped region and a salicide region, the first doped region comprises a first side adjacent to the gate and a second side, the second doped region is deeper than the first doped region and adjacent to the second side of the first doped region, the salicide region is disposed in the second doped region and spaced from the second side of the first doped region by a distance defined by a portion of a mask.

11. The structure as claimed in claim 10, further comprising a first spacer adjacent to the gate and over the first doped region.

12. The structure as claimed in claim 11, further comprising a second spacer adjacent to the first spacer, wherein the distance is defined by the second spacer.

13. The structure as claimed in claim 11, wherein each first spacer comprises stack films of silicon oxide and silicon nitride.

14. The structure as claimed in claim 12, wherein each second spacer is silicon nitride or silicon oxy-nitride.

15. The structure as claimed in claim 12, wherein each second spacer has a width of 100 Å˜500 Å.

16. A structure of a low leakage MOS transistor, comprising:
a substrate;
a gate disposed on the substrate; and
at least two electrodes in the substrate and adjacent to the gate, each comprising a first region, a second region and a third region, the first region with a first resistance R1, the second region with a second resistance R2 and the third region with a third resistance R3, wherein R3<R2<R1, and the third region spaced apart from the first region by a distance defined by a portion of a mask.

17. The structure as claimed in claim 16, wherein the second region is deeper than the first region.

18. The structure as claimed in claim 16, wherein the third region is a salicide region.
